(19) United States
(12) Patent Application Publication
(10) Pub. No.: US 2013/0269759 A1
(43) Pub. Date: Oct. 17, 2013

(54) PROGRAMMABLE GAIN AMPLIFIER WITH MULTI-RANGE OPERATION FOR USE IN BODY SENSOR INTERFACE APPLICATIONS

(71) Applicants: Jani Oksanen, Espoo (FI); Jaakko Tulkki, Helsinki (FI)

(72) Inventors: Jani Oksanen, Espoo (FI); Jaakko Tulkki, Helsinki (FI)

(21) Appl. No.: 13/256,473

(22) PCT Filed: Mar. 18, 2010
(86) PCT No.: PCT/FI2010/050208

§ 371 Date: Jun. 28, 2012

(30) Foreign Application Priority Data
Mar. 19, 2009 (FI) 20095286

(51) Int. Cl. H01L 31/04

(52) U.S. Cl. CPC H01L 31/0406
USPC 136/253

(57) ABSTRACT

A method and device for generating electrical energy in a thermophotonic generator, where electroluminescence and heat energy absorbed from the environment is used to generate light or other electromagnetic radiation that transfers energy from the emitting element to the absorbing element, where a part of the energy of the absorbed radiation generates electrical energy.

### BACKGROUND

1. Field

The aspects of the disclosed embodiments relate in general to converting heat energy to electrical energy.

2. Brief Description of Related Developments

Known methods to convert heat energy to electrical energy conventionally utilize e.g. solid state devices based on the thermoelectric effect of mechanical turbines. The weaknesses of these methods are the very low efficiency in case of the thermoelectric effect and the large size and the need for very high temperature difference in case of the mechanical turbines.

### SUMMARY

One aspect of the disclosed embodiments is a method for converting heat energy to electrical energy in a thermophotonic generator, where heat energy is transferred with the aid of light or other electromagnetic radiation generated in a structure by electroluminescence from an element emitting radiation and absorbing heat to an element absorbing radiation through a thermally insulating layer that does not substantially hinder the transport of photons between these elements, the electromagnetic radiation is transferred in the direction defined by the second law of thermodynamics and the transferred heat energy is converted into electrical energy in the element absorbing the radiation.

In the aspects of the disclosed embodiments heat energy absorbed from the environment is partly utilized in generating light or other electromagnetic radiation that transports energy from the emitting element to the absorbing element, where a part of the absorbed heat energy generates electrical energy. In certain embodiments light or other electromagnetic radiation is produced as an intermediate energy form by using the heat energy of a hot heat reservoir.

In aspects of the disclosed embodiments, light or other electromagnetic radiation may be used to convert heat energy to electrical energy in a solid state generator that operates between two heat reservoirs at different temperatures. Certain embodiments of the invention may achieve the benefits of the Peltier element as a compact solid state generator, but also reach a higher efficiency than typically with a Peltier element. In the electricity generation method of certain embodiments of the invention, radiation emitted by an element emitting light or other electromagnetic radiation by using electrical energy and heat energy is coupled to an element absorbing radiation, in which a part of the heat energy contained in the radiation is converted to electrical energy. When the temperature of the emitting element (or the hot heat reservoir) is larger than the temperature of the absorbing element (or the cold heat reservoir), the electrical power generated by the absorbing element can be larger than the electrical power consumed by the emitting element. In certain embodiments, energy is transferred from the emitting element to the absorbing element with the aid of photons. The radiation emitted by the emitting element may be, for example, light produced by electroluminescence in semiconductors. The heat conduction between the emitting and the absorbing element, that reduces the efficiency, can be decreased by placing a thermally insulating layer between them, through which the radiation emitted by the emitting element can pass substantially unhindered. The thermally insulating layer can be implemented for example by separating the emitting and the absorbing element from one another by nanoparticles scattered sparsely on their surfaces and by creating a vacuum in the gap thus formed between the elements. In certain other embodiments the nanostructure may be continuous so that there is no empty space between the emitting and the absorbing element.

In certain embodiments the emitting and the absorbing element have been coupled to one another by an element that is transparent to electromagnetic radiation.

In certain embodiments efficient transport of light or other electromagnetic radiation between the emitting element and the absorbing element is arranged by enclosing the emitting element and the absorbing element in the same optical cavity.

In certain embodiments the efficient transport of light or other electromagnetic radiation in between the emitting element and the absorbing element is arranged by connecting the emitting element and the absorbing element to one another by (i) a material layer whose refractive index has been substantially matched with the emitting and the absorbing element.

In certain embodiments the efficient transport of light or other electromagnetic radiation in between the emitting element and the absorbing element is arranged by connecting the emitting element and the absorbing element to one another by (ii) a material or a vacuum layer that has a refractive index substantially different from the refractive index of the emitting and the absorbing element and that is so thin that it does not substantially hinder the transport of photons across the layer.

In certain embodiments the efficient transport of light or other electromagnetic radiation in between the emitting element and the absorbing element is arranged by connecting the emitting element and the absorbing element to one another by (iii) nanoparticles or nanostructures so that the space between the nanoparticles or the nanostructures forms between the connected elements a gap that is so thin that it does not substantially hinder the transport of photons across the gap.

In certain embodiments the efficient transport of light or other electromagnetic radiation in between the emitting element and the absorbing element is arranged by connecting the emitting element and the absorbing element to one another by (iv) an substantially lossless wave guide that does not substantially hinder the transport of radiation.

In certain embodiments the efficient transport of light or other electromagnetic radiation in between the emitting element and the absorbing element is arranged by connecting the emitting element and the absorbing element to one another by (v) any structure or structures combining and/or repeating the structures in the above items (i)-(iv).

In certain embodiments the efficient transport of light or other electromagnetic radiation between the emitting element and the absorbing element is arranged by enclosing the emitting element and the absorbing element in the same optical cavity and by connecting the emitting and the absorbing element to one another by any structure according to the above items (i)-(v) or a combination thereof.

In certain embodiments at least some layer(s) in the structures in accordance with the above items (i)-(v) may function as thermally insulating layer(s).

In certain embodiments the emitting element is a semiconductor structure and/or includes a light emitting diode. In certain embodiments the absorbing element is a semiconductor structure and/or includes a light emitting diode.

In certain embodiments heat is transferred between two light emitting diode structures, in between which there is at least one thermally insulating material layer or a vacuum, that is so thin that it allows the transport of the radiation over the thermal insulator.

In certain embodiments the material layer used as a thermal insulator between the emitting and the absorbing element has been implemented by using small particles so that the space in between the particles is a vacuum or consists of another thermally insulating material.

In certain embodiments implemented with semiconductors the injection of the charge carriers into the semiconductor takes place through an electrical contact where in a large part of the contact the semiconductor and metal functioning as the contact have been separated from one another by a material layer or a vacuum with a differing refractive index and where the current transport in between the semiconductor and the metal takes place through protrusions extending over the layer. In certain embodiments the protrusions may have been fabricated by growing them on the surface of the semiconductor.

In accordance with another second aspect of the disclosed embodiments there is provided a device that converts heat energy into electrical energy and comprises: an element emitting radiation and absorbing heat, hereinafter called the emitter, configured to transfer heat in the direction defined by the second law of thermodynamics by using light or other electromagnetic radiation generated by electroluminescence to an element absorbing radiation, hereinafter called the absorber, the absorber configured to absorb the electromagnetic radiation emitted by the emitter and to convert energy contained in it to electrical energy, and a thermally insulating layer between the emitter and the absorber that does not substantially hinder the transport of radiation between the emitter and the absorber.

In certain embodiments the device comprises an element emitting light optically coupled to an element absorbing light between which energy is transferred by using light. The emitting element absorbs heat from the hot heat reservoir and transfers it by using light to the absorbing element, where a part of the heat can be converted into electrical energy and a part of the heat is released in the cold heat reservoir.

The said device can be a device using photons to convert heat into electricity, that is, a thermophotonic generator. Its advantages compared to mechanical generators are the small size and the lack of moving parts.

In certain embodiments a material layer used as a thermal insulator between the emitting and the absorbing element has been implemented by using small particles so that the space in between the particles is a vacuum or consists of another thermally insulating material so that the thermally insulating material layer is so thin that it allows efficient coupling of the light over the thermal insulator, but the small contact area of the particles reduces the heat transfer between the elements.

In certain embodiments the injection of the charge carriers into the emitting and/or the absorbing element has been configured to take place through an electrical contact where the emitting element and the metal functioning as the contact have been separated from one another in a part of the contact by a material layer or a vacuum of differing refractive index and the current transport between the element and the metal takes place along protrusions extending over the layer, which enable the electrical contact between the emitting element and the metal.

The method and device in accordance with the embodiments of the invention can be used for generating electrical energy for example in fireplaces, stoves, solar energy harvesters or other circumstances where a temperature gradient is available.

In some embodiments implemented with semiconductors the energy gap of the active region in the emitting element is smaller than energy gaps of the doped semiconductors on both sides or (or surrounding) the active region.

In accordance with yet another aspect of the disclosed embodiments there is provided an optical or an electrical device that includes a device that converts heat energy into electrical energy generally as a part of the optical or the electrical device or in particular integrated on the same substrate with an electrical or an optical integrated circuit, the device that converts heat energy into electrical energy comprising: an element emitting radiation and absorbing heat, hereinafter called the emitter, configured to transfer heat in the direction defined by the second law of thermodynamics by using light or other electromagnetic radiation generated by electroluminescence to an element absorbing radiation, hereinafter called the absorber, the absorber configured to absorb the electromagnetic radiation emitted by the emitter and to convert energy contained in it to electrical energy, and a thermally insulating layer between the emitter and the absorber that does not substantially hinder the transport of radiation between the emitter and the absorber.

Certain aspects of the disclosed embodiments are described in the detailed description and in the dependent claims. The embodiments are described in the context of certain selected aspects of the invention. The person skilled in the art will understand that any embodiment may typically be combined with another embodiment or other embodiments under the same aspect of the disclosure. Any embodiment may also typically be combined with another aspect or other aspects of the disclosed embodiments by itself or together with any other embodiment of embodiments.

### BRIEF DESCRIPTION OF THE DRAWINGS

FIG. 1 shows an example of the principle of electricity generation in an embodiment of the invention

FIG. 2 is an example of a structure or a cross section of a device enabling the disclosed electricity generation method.

### DETAILED DESCRIPTION

In the following examples of the operation principle and the structure of a thermophotonic generator using light are described according to certain embodiments of the invention. It should be noted that instead of light, the thermophotonic generator may transfer heat by using another form of electromagnetic radiation.

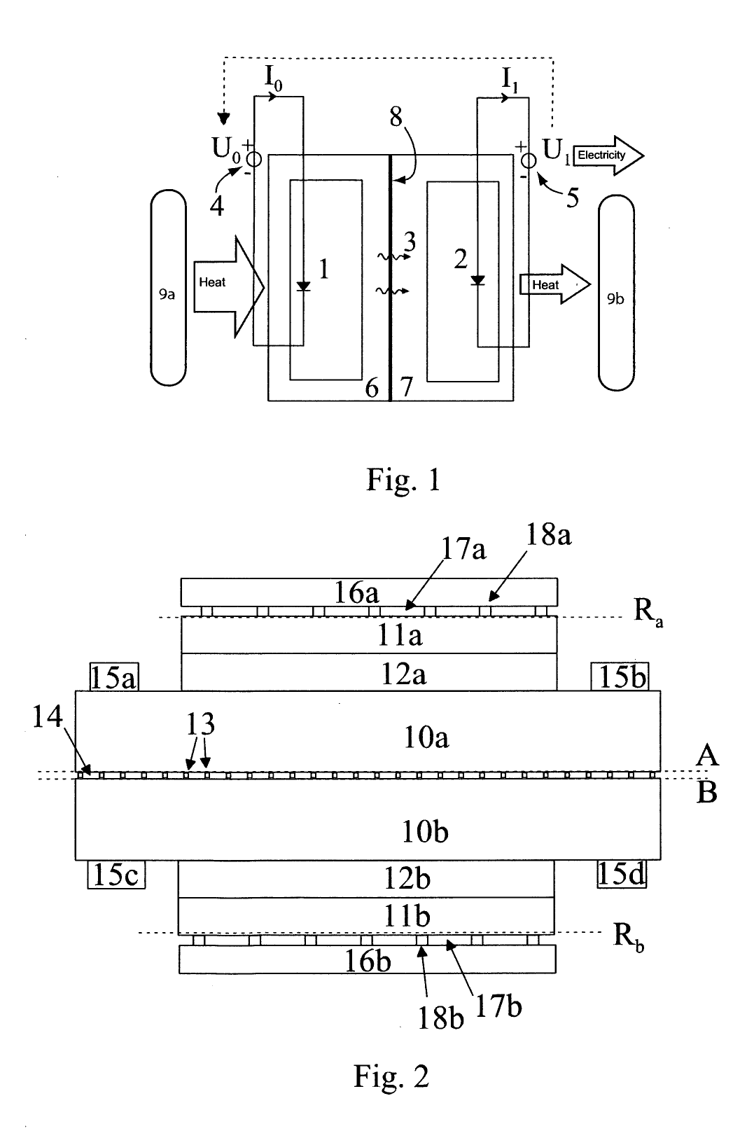

In FIG. 1 the element 1 emitting radiation emits radiation 3 by using an external energy source 4 and heat energy obtained from the hot heat reservoir 9a. Element 1 can include for example a light emitting diode that emits light by electroluminescence and the external energy source 4 can be a voltage source (or more generally an energy source) U₀, that injects a current I₀ for the light emitting diode through the electrical circuit of FIG. 1. The emitted radiation 3 is transferred to the element 2 absorbing radiation, where a part of the energy contained by the radiation is given to an external element 5 and a part is restored as heat that is released to the cold heat reservoir 9b. If the temperature of the element 1 is larger than the temperature of element 2, the electrical power given to the external element 5 can be larger than the electrical energy consumed by element 4 to emit light, and the generator produces electrical energy. Element 2 can be for example a light emitting diode operating as a photovoltaic cell that generates a voltage U₁ and a current I₁, and feeds the produced electrical energy through the electrical circuit to element 5, from where it can be extracted. A part of the energy received by element 5 can also be used in aid or instead of the external energy source 4 in generating the radiation emitted by element 1 by the feedback loop represented by the dashed line. The high efficiency of the device is in certain embodiments partly based on the nearly monochromatic spectrum of the light emitted by the emitting element 1 powered by the external voltage source, which allows the light to be efficiently converted to electricity in the light emitting diode operating as a photovoltaic cell. The area 6 surrounding the emitting element 1 can be thermally connected to the hot heat reservoir 9a from where it receives heat energy, and can include for example elements belonging structurally to element 1, such as the substrate and/or electrical contacts. Area 6 is separated from the area 7 surrounding the absorbing element 2 by a thermally insulating area 8 which reduces the conduction of heat between the emitting element 1 and the absorbing element 2, but is transparent to the electromagnetic radiation between the emitting element 1 and the absorbing element 2. Area 7 may be thermally connected to the cold heat reservoir 9b and can include elements corresponding to the elements around element 1. Areas 8, 6 and 7 form in this embodiment an optical cavity that enables strong optical coupling between elements 1 and 2. The term optical cavity should be interpreted widely in this document: it can mean the optical cavities formed by areas 6 and 7 independently as well as the cavity they form together when they are optically coupled by area 8.

FIG. 2 represents an example of a cross section of a device or a structure that utilizes the disclosed energy conversion method. For the sake of the clarity of the figure, the structure has not been drawn to correct scale, and in reality the width of the structure is much larger than the height. In FIG. 2 the emitting element is formed by the part above intersection A and the absorbing element is formed by the part below intersection B. Both the emitting and the absorbing element can in practice comprise a semiconductor diode structure, metallic contacts and a mirror structure.

In certain embodiments the emitting element operates so that photons are generated when charge carriers, that are injected to the active area 12a through metallic contacts 15a,b and 16a and doped semiconductor layers 10a (n-type doping) and 11a (p-type doping), recombine. When the materials are of high quality, the energy of the emitted photons is larger than the energy provided by the external power source. The part of the energy of the emitted photons that is not provided by the external energy source is provided by the heat energy of the emitting element.

In certain embodiments the absorbing element is a light emitting diode structure that operates as a photovoltaic cell, where the photons emitted by the emitting element are absorbed in the active region 12b at a very high quantum efficiency. The carriers generated in the active region produce through the doped semiconductor layers 10b (n-doped) and 11b (p-doped) and the metallic contacts 15c, 15d and 16b an electric current in the external circuit that allows the recovery of a part of the energy of the photons as electrical energy. If the temperature of the emitting element is larger than the temperature of the absorbing element, the electrical power generated by the absorbing element can be larger than the electrical power consumed by the emitting element.

Connecting the structure to external elements, like the external energy sources of FIG. 1, takes place through contacts 15a-d, 16a,b. In certain embodiments the external voltage source U₀ of FIG. 1 feeds energy to the emitting element through contacts 15a,b and 16a and generates photons by electroluminescence or another applicable mechanism. The external circuit U₁ correspondingly receives energy from the element absorbing photons and can redirect a part of the received energy back to the emitting element to be reused in the emission of photons. When the device is packaged the structure of FIG. 2 may be connected to the external circuits, encapsulated tightly and evacuated of any gases. The emitting element is thermally connected to the hot heat reservoir 9a and the absorbing element is thermally connected to the cold heat reservoir 9b. To improve the performance of the device, heat conducting elements like heat pipes, heat sinks and/or fans can be placed between the side absorbing the heat energy and the hot heat reservoir and the side generating heat energy and the cold heat reservoir to keep the temperature differences small between the heat reservoirs and the parts of the device that are in contact with them.

The operation of the device in FIG. 2 as an efficient generator is based, depending on the embodiment, on the very high quantum efficiency of photon emission and absorption, strong optical coupling of the emitting and the absorbing element, small heat conduction between the emitting and the absorbing element and small resistive losses. To accomplish these requirements, following factors play a role:

(1) The absorption of the emitted photons outside the active regions 12a,b should be small. This can be accomplished for example by fabricating the doped semiconductor layers 10a,b and 11a,b from indium phosphide and the active regions 12a,b from a GaAsSb or InGaAs-layer whose energy gap is smaller that in the InP layers. The semiconductor layers 10a,b, 11a,b and 12a,b should be lattice matched with the substrate or pseudomorphic i.e. strained structures in which the strain has not relaxed through the formation of dislocations. The thickness of the active regions 12a,b can typically be of the order of the wavelength of light, the thickness of the semiconductor layers 11a,b can be of the order of the diffusion length of the holes and the thickness of the semiconductor layer 10a,b can be of the order of the thickness of the substrate and it can be formed of the substrate itself, provided that the optical losses of the substrate material are sufficiently small. Other compound semiconductors that enable light emission based on electroluminescence and absorption, and that can be used to fabricate a structure where the energy band gap of the active region is smaller than the energy gap of the doped semiconductor layers can be used to fabricate the device of FIG. 2 as well. For example using GaAs/AlGaAs material system is possible, but typically requires removing the GaAs substrate from the complete structure in order for the absorption of the substrate not to cause problems.

(2) The optical coupling between the emitting element and the absorbing element should be strong so that the transport of photons between the elements occurs with a high efficiency, but simultaneously the heat conduction between the elements should be small. The strong optical coupling can be obtained for example by placing the emitting and the absorbing element inside the same optical cavity and/or inside material that has effectively the same refractive index as the emitting and the absorbing material so that the photon transport between the emitting and the absorbing material takes place within material that has an effectively homogeneous refractive index. The small thermal conductivity and strong optical coupling between the structures can be achieved for example by fabricating the structure in FIG. 2 in two parts so that the emitting and the absorbing element are fabricated separately and placed close to one another for example by attaching them together using small particles 13. The particles can be for example commercially available nanoparticles scattered between the emitting and the absorbing element, self organized quantum dots grown in the gap or nanostructures processed in the gap. Then the gap between the elements can be made so thin that it allows efficient coupling of light between the elements, but the small contact area of the particles 13 will strongly reduce the heat conduction by phonons between the elements. When the device is packaged a vacuum can also be formed in area 14, which further significantly reduces the heat conduction between the elements.

(3) The absorption losses at the interfaces Rₐ and R_{b} of the semiconductor layers 11a,b and the metal contacts 16a,b should be small. To this end, air gaps 17a,b that fill most of the area between the semiconductor and the reflector or contact metal can be used to increase the portion of the internal total reflection at the interfaces of the semiconductors and the air gaps without giving rise to excessive resistive losses. In the configuration of FIG. 2 the actual electrical contacting takes place through the electrically conducting extrusions 18a,b fabricated to the surface of the semiconductor with a suitable fill factor. Also other mirror structures with a high coefficient of reflectivity are suitable for this purpose.

(4) Reaching a high external quantum efficiency typically requires a large internal quantum efficiency. This requirement can be reached by using high quality materials, advanced fabrication technology and optimization of the structure. The proportion of the nonradiative recombination taking place at the surfaces of the structure can be reduced by passivating the interfaces close to the active regions 12a,b, which reduces the amount of the nonradiative surface states and allows reducing the rate of recombination through these states.

(5) The resistive losses of the structure should be small. The electric contacts 15a-d to the structure in regions 10a,b can be made through the side and in areas 11a,b so that light is efficiently reflected by the interface between the semiconductors 11a,b and the electrical contacts 16a,b. Since the width of the structure is considerably larger than the thickness, the current transport in the structure is mainly lateral between contacts 15a,b and 16a and between contacts 15b,d and 16b. The resistive losses in the structure represented in FIG. 2 can be affected by optimizing the width of the structure, the thickness and doping concentration of the semiconductor layers 10a,b and 11a,b and the fill factor of the contact extrusions 18a,b.

The method in accordance with an embodiment of the disclosure described above can be exploited by various structures of which only an example has been presented above. Other modifications are for example structures made of other materials than inorganic semiconductors and structures in which optical fibers, photonic crystals, other wave guides or non-reciprocal components like optical isolators based on Faraday rotation are used to transport photons between the emitter and the absorber. Furthermore the structure can also be integrated as a part of an electrical or optical integrated circuit which may allow further advantages in fabrication technology.

The foregoing description provides non-limiting examples of certain embodiments of the invention. It is clear to a skilled person that the invention is not restricted to the presented details and that the aspects of the present disclosure can also be implemented using other equivalent ways. In this document the terms comprise and include are open expressions and they are not meant to be limiting.

Some of the features of the presented embodiments can be utilized without using other features. As such, the foregoing description shall be considered as merely illustrative of the principles of the present invention, and not in limitation thereof. The scope of the invention is only restricted by the appended patent claims.

What is claimed is:

1. A method for converting heat energy to electrical energy in a thermophotonic generator comprising:
transferring heat energy, with the aid of light or other electromagnetic radiation generated, in a structure by electroluminescence from an element emitting radiation and absorbing heat to an element absorbing radiation through a thermally insulating layer that does not substantially hinder the transport of photons between these elements,
transferring the electromagnetic radiation in a direction defined by the second law of thermodynamics and
converting the transferred heat energy into electrical energy in the element absorbing the radiation.

2. A method as claimed in claim 1, wherein the emitting and the absorbing element have been coupled by an element that is transparent to the electromagnetic radiation.

3. A method as claimed in claim 1, wherein the emitting element and/or the absorbing element is a semiconductor structure and/or includes a light emitting diode.

4. A method as claimed in claim 1, wherein the efficient transport of the light or other electromagnetic radiation between the emitting and the absorbing element is arranged by
enclosing the emitting element and the absorbing element in the same optical cavity and/or by connecting the emitting and the absorbing element to one another by
(i) a material layer whose refractive index has been substantially matched with the emitting and the absorbing element, or
(ii) a material or a vacuum layer whose refractive index substantially differs from the refractive index of the emitting and the absorbing element, but is so thin that it does not substantially hinder the transport of photons across the layer, or
(iii) nanoparticles or nanostructures so that the space between the nanoparticles or nanostructures forms between the combined structures a gap that is so thin that is does not substantially hinder the transport of photons across the gap, or
(iv) an substantially lossless wave guide that does not substantially hinder the transport of radiation, or
(v) any structure or structures combining and/or repeating the structures in the above items (i)-(iv), where some material layer(s) function as thermally insulating layers.

5. A method as claimed in claim 1, wherein heat is transferred between two light emitting diode structures separated by at least one thermally insulating material layer or vacuum that is so thin that it allows transport of radiation over the layer.

6. A method as claimed in claim 1, where a thermally insulating material layer in between the emitting and absorbing elements has been implemented by using small particles so that the space in between the particles is a vacuum or consists of another thermally insulating material.

7. A device that converts heat energy into electrical energy and comprises:
an element emitting radiation and absorbing heat, hereinafter called the emitter, configured to transfer heat in the direction defined by the second law of thermodynamics by using light or other electromagnetic radiation generated by electroluminescence to an element absorbing radiation, hereinafter called the absorber,
wherein the absorber is configured to absorb the electromagnetic radiation emitted by the emitter and to convert energy contained in it to electrical energy, and
a thermally insulating layer between the emitter and the absorber that does not substantially hinder the transport of radiation between the emitter and the absorber.

8. A device as claimed in claim 7, wherein the emitting and the absorbing element have been connected by an element that is transparent to the electromagnetic radiation.

9. A device as claimed in claim 7, wherein the emitting element and/or the absorbing element is a semiconductor structure and/or includes a light emitting diode.

10. A device as claimed in claim 7, wherein efficient transport of the light or other electromagnetic radiation between the emitting and the absorbing element is arranged by
enclosing the emitting element and the absorbing element in the same optical cavity and/or connecting the emitting and the absorbing element to one another by
(i) a material layer whose refractive index has been substantially matched with the emitting and the absorbing element, or
(ii) a material or a vacuum layer whose refractive index substantially differs from the refractive index of the emitting and the absorbing element, but is so thin that it does not substantially hinder the transport of photons across the layer, or
(iii) nanoparticles or nanostructures so that the space between the nanoparticles or nanostructures forms between the combined structures a gap that is so thin that is does not substantially hinder the transport of photons across the gap, or
(iv) an substantially lossless wave guide that does not substantially hinder the transport of radiation, or
(v) any structure or structures combining and/or repeating the structures in the above items (i)-(iv), where some material layer(s) function as thermally insulating layers.

11. A device as claimed in claim 7, wherein the thermally insulating material layer in between the emitting and absorbing element has been implemented by using small particles so that a space in between the particles is a vacuum or consists of another thermally insulating material so that the thermally insulating material layer is so thin that it allows efficient coupling of the light over the thermal insulator, but the small contact area of the particles reduces the heat conduction between the elements.

12. A device as claimed in claim 7, wherein injection of charge carriers into the emitting and/or the absorbing element has been configured to take place through an electrical contact and where the element and metal functioning as the contact have been separated from one another by a material layer or a vacuum of differing refractive index in a part of the contact and the current transport in between the emitting element and the metal has been configured to take place across protrusions that extend over the layer and that enable the electrical contact between the emitting element and the metal.

13. A device as claimed in claim 7, wherein the device has been configured to use wave guides, optical fibers or nonresiprocal components like optical isolators based on Faraday rotation in the transfer of electromagnetic energy.

14. An optical or an electrical device that includes a device of claim 7 generally as a part of the optical or the electrical device or in particular integrated on the same substrate with an electrical or an optical integrated circuit.
